(19) United States
(12) Patent Application Publication
(10) Pub. No.: US 2025/0201681 A1
(43) Pub. Date: Jun. 19, 2025

(54) WIRE BONDING USING A FLOATING PAD

(71) Applicant: SEMICONDUCTOR COMPONENTS INDUSTRIES, LLC, Scottsdale, AZ (US)

(72) Inventors: Hiroshi INOGUCHI, Tatebayashi City (JP); Hirotada HONMA, Tokyo (JP)

(73) Assignee: SEMICONDUCTOR COMPONENTS INDUSTRIES, LLC, Scottsdale, AZ (US)

(21) Appl. No.: 18/543,644

(22) Filed: Dec. 18, 2023

(51) Int. Cl. H01L 23/495; H01L 23/00

(52) U.S. Cl. CPC H01L 23/49575; H01L 23/49562; H01L 24/29; H01L 24/32; H01L 24/45; H01L 24/48; H01L 24/73; H01L 24/85; H01L 2224/2919; H01L 2224/32245; H01L 2224/45124; H01L 2224/45144; H01L 2224/48245; H01L 2224/73265; H01L 2224/85; H01L 2924/07025

(57) ABSTRACT

A semiconductor device module for use in high-power applications incorporates a lead frame and a wire bonding scheme designed to improve reliability and reduce cost. A combination of aluminum wire bonds and gold wire bonds can be used to connect dies of different sizes, formed on different substrates, or that use different bonding materials to a shared underlying structure. Instead of making direct connections between the dies, the different types of wire bonds can be coupled to an intermediate floating pad.

### TECHNICAL FIELD

This description relates to assembling and packaging semiconductor device modules, semiconductor device assemblies, and semiconductor devices. More specifically, this description relates to reliability of wire bonds that form connections between chips in a semiconductor module.

### BACKGROUND

Semiconductor device assemblies, e.g., chip assemblies that include power semiconductor devices, can be implemented using multiple semiconductor dies, substrates (e.g., die attach pads (DAPs)), electrical interconnections, and a molding compound. Power transistors can include, for example, insulated-gate bipolar transistors (IGBTs), power metal-oxide-semiconductor field effect transistors (MOSFETs), and so forth. Fast recovery diodes (FRDs) may be used in conjunction with power transistors. Electrical interconnections within a high-power semiconductor device module can include, for example, bond wires, conductive spacers, and conductive clips. A polymer molding compound can serve as an encapsulant to protect components of the device assembly. Such high-power chip assemblies, encapsulated as semiconductor device modules, can be used in various applications, including electric vehicles (EVs), hybrid electric vehicles (HEVs), and industrial applications.

### SUMMARY

In some aspects, the techniques described herein relate to an apparatus, including: a substrate; a first die on the substrate, the first die having a current sense area; a first wire bond coupled to the first die at plurality of bonding points; and a second die on the substrate, the second die coupled to the current sense area by a second wire bond.

In some aspects, the techniques described herein relate to an apparatus, wherein the second die is attached to the substrate by a polyimide tape.

In some aspects, the techniques described herein relate to an apparatus, wherein one of the plurality of bonding points is in the current sense area.

In some aspects, the techniques described herein relate to an apparatus, wherein the first die is an insulated gate bipolar transistor (IGBT), and the current sense area is internal to the IGBT.

In some aspects, the techniques described herein relate to an apparatus, wherein one of the plurality of bonding points is at an emitter of the IGBT.

In some aspects, the techniques described herein relate to an apparatus, wherein the first wire bond is configured to carry a current between the emitter and ground and no current between the emitter and the current sense area.

In some aspects, the techniques described herein relate to an apparatus, wherein a first bonding pad at the current sense area for the first wire bond is separated from a second bonding pad at the current sense area for the second wire bond.

In some aspects, the techniques described herein relate to an apparatus, wherein a material of the first wire bond includes aluminum.

In some aspects, the techniques described herein relate to an apparatus, wherein a material of the second wire bond includes gold.

In some aspects, the techniques described herein relate to an apparatus, wherein the first wire bond is grounded to a lead frame.

In some aspects, the techniques described herein relate to an apparatus, wherein the controller is configured to sense current in the first wire bond.

In some aspects, the techniques described herein relate to an apparatus, wherein the current sense area is configured to operate without current flow.

In some aspects, the techniques described herein relate to an apparatus, wherein the current sense area is electrically floating.

In some aspects, the techniques described herein relate to an apparatus, wherein the first wire bond and the second wire bond are coupled to bonding points by gold balls.

In some aspects, the techniques described herein relate to a method, including: coupling an emitter of an insulated gate bipolar transistor (IGBT) device on a substrate to a current sense area via a first wire bond; coupling a controller adjacent to the IGBT device on the substrate to the current sense area via a second wire bond; monitoring, by the controller, a voltage at the emitter using the first wire bond; and determining from the voltage an emitter current.

In some aspects, the techniques described herein relate to a method, wherein coupling to a current sense area includes coupling to a floating pad.

In some aspects, the techniques described herein relate to a method, further including coupling the emitter to ground via the first wire bond.

In some aspects, the techniques described herein relate to an apparatus, including: a first integrated circuit (IC) chip coupled to a lead frame, the first IC chip attached to a substrate using solder; a second IC chip attached to the substrate using polyimide tape; a first wire bond coupling the lead frame to the first IC chip; and a second wire bond coupling the first IC chip to the second IC chip.

In some aspects, the techniques described herein relate to an apparatus, wherein the second IC chip is configured to monitor and control the first IC chip via a floating current sense pad.

In some aspects, the techniques described herein relate to an apparatus, wherein the first wire bond and the second wire bond are both coupled to the floating current sense pad.

### BRIEF DESCRIPTION OF THE DRAWINGS

FIG. 1 is a high level schematic diagram of a semiconductor device module, according to some implementations of the present disclosure.

FIG. 2 is a pictorial perspective view of the semiconductor device module shown in FIG. 1, according to some implementations of the present disclosure.

FIG. 3 is a top side plan view of the semiconductor device module shown in FIG. 2, according to some implementations of the present disclosure.

FIG. 4 is a pictorial perspective view of the semiconductor device module shown in FIG. 1, according to some implementations of the present disclosure.

FIG. 5 is a pictorial perspective view of the semiconductor device module shown in FIG. 1, according to some implementations of the present disclosure.

FIG. 6 is a flow diagram illustrating a method of configuring a semiconductor device module, according to some implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

Wiring between integrated circuit (IC) chips in a semiconductor module is inherently vulnerable to damage or breakage. Consequently, a sub-optimal wire bonding arrangement can cause yield and/or reliability failures that can result in decreased revenue and increased IC fabrication cost. This concern is particularly significant for high-power modules that carry high currents and include expensive materials such as silicon carbide (SiC), high tech ceramics made of silicon nitride (Si₃N₄), and direct bond metal (DBM) structures, e.g., direct bond copper (DBC) structures. When these high-power modules are manufactured in large volume, even a small reduction in per unit cost can add up to substantial savings.

This disclosure relates to implementations of a high-power semiconductor module that is efficiently laid out on a multi-layer copper structure, with a carefully designed wire bonding configuration. Judicious use of aluminum and gold wire bonds as well as proper placement of a floating current sense pad provide a solution that is both low-cost and highly reliable. Although the implementations described herein are directed to a circuit for use in high-power applications, by way of example, other types of circuits can use a similar wire bond configuration to achieve similar advantages as described herein.

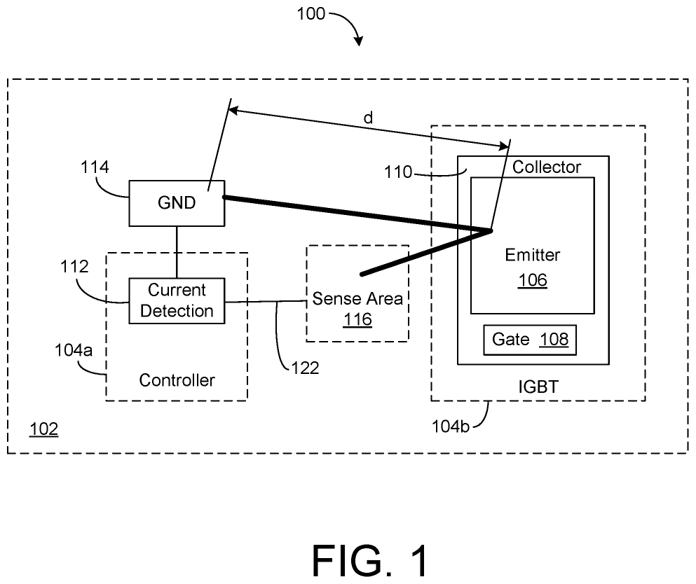

FIG. 1 is a high level block diagram of a semiconductor device module 100, in accordance with some implementations of the present disclosure. The semiconductor device module 100 includes a substrate in the form of a die attach pad (DAP) 102, and at least two electronic components, e.g., semiconductor dies or chip assemblies 104 (two shown, a first chip assembly 104a and a second chip assembly 104b). The chip assemblies 104 can be attached to, e.g., mounted on, or coupled to, a top surface of the die attach pad (DAP) 102 by a bonding agent, e.g., an epoxy, a solder, a silver (Ag) sintering material, and/or an adhesive. In some implementations, the first chip assembly 104a and the second chip assembly 104b can be coupled to the DAP 102 by two different bonding agents.

In some implementations, the first chip assembly 104a is a controller and the second chip assembly 104b is an insulated gate bipolar transistor (IGBT). The controller controls the IGBT and serves as a protection device for the IGBT. For example, the controller can provide temperature protection and/or over-voltage protection for the IGBT. The controller can also limit the amount of current delivered to the IGBT, necessitating a current sensing function. The controller can be configured to monitor the IGBT via the sense area 116. In some implementations, the controller includes a current detection pad 112. The IGBT is a three-terminal device that includes an emitter 106, a gate 108, and a collector 110. However, other types of semiconductor dies, e.g., MOSFETs, diodes, and so forth, can be used as one or more of the chip assemblies 104.

The chip assemblies 104 can be fabricated on various types of semiconductor substrates, e.g., semiconductor wafers, for example, silicon (Si), silicon carbide (SiC), gallium (Ga), gallium nitride (GaN), aluminum gallium nitride (AlGaN), gallium arsenide (GaAs), aluminum gallium arsenide (AlGaAs), indium phosphide (InP), glass substrates, sapphire substrates, and so on. In some implementations, the chip assemblies 104 can be fabricated on different substrates. For example, the IGBT can be fabricated on a silicon substrate while the controller can be fabricated on a SiC substrate. In some implementations, the chip assemblies 104 are both fabricated on a SiC substrate.

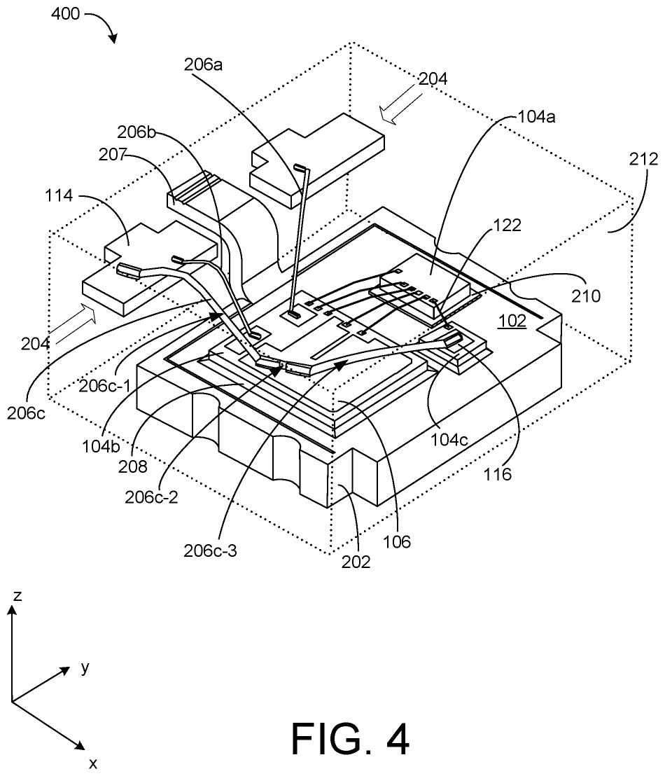

The semiconductor device module 100 can further include a ground 114 and a floating pad for use as a sense area 116. The ground 114 can be located separately from both chip assemblies 104. The ground 114 can be coupled to the current detection pad 112 on the controller. The ground 114 can also be coupled to the emitter 106 of the IGBT. The ground 114 can be coupled to the emitter 106 by a wire bond of length d, having an extension that couples the emitter 106 to the sense area 116. The controller can be coupled to the sense area 116 by a wire bond 122. The sense area 116 can be disposed on the chip assembly 104b as shown in FIG. 1, or on an island between the chip assembly 104b and the chip assembly 104a, as shown in FIG. 4.

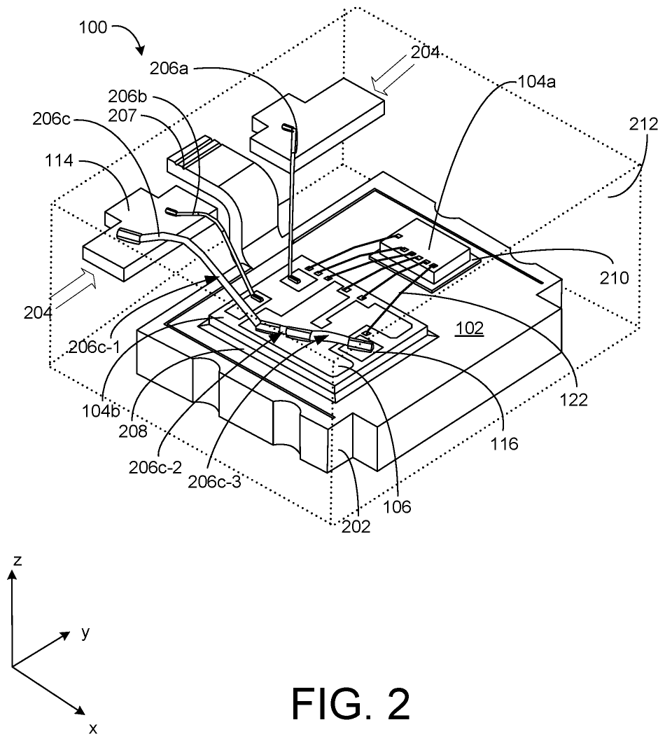

FIG. 2 is a pictorial perspective view of the semiconductor device module 100, in accordance with some implementations of the present disclosure. FIG. 2 shows that the IGBT die, chip assembly 104b, has a much larger footprint (e.g., area, when viewed from above), e.g., about 2 to 3 times larger, than the controller die, chip assembly 104a. In some implementations, the emitter 106 of the IGBT is extensive (e.g., has a relatively large area) and has an irregular shape. The IGBT die may include, in addition to the power transistor, auxiliary devices such as, for example, temperature sensors and electrostatic discharge (ESD) detectors.

In addition to the components shown in FIG. 1, the pictorial view shown in FIG. 2 illustrates structural elements of the semiconductor device module 100, such as a direct bond metal (DBM) structure 202, a lead frame 204, and an encapsulant 212. The lead frame 204 provides signal paths from the semiconductor device module 100 to external devices, power supplies, and ground connections. The lead frame 204 as shown in FIG. 2 includes elements such as the ground 114 and a rigid S-shaped connector 207. In some embodiments, the lead frame 204 can be disposed in a different plane than the DBM structure 202, for example, the lead frame 204 can be on a level above the DBM structure 202.

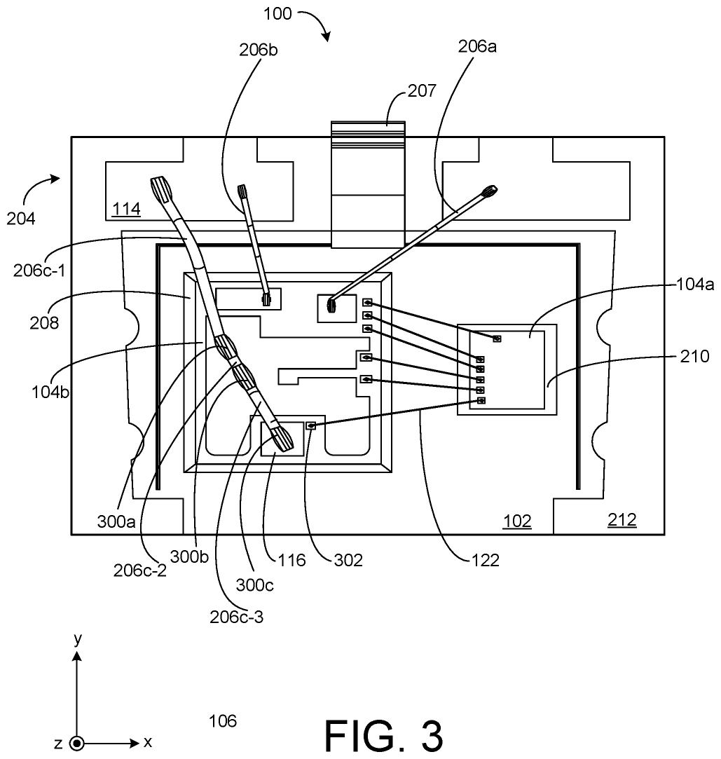

FIG. 2 shows that the DBM structure 202 is substantially square. In some implementations, the DAP to which the chip assemblies 104 are mounted can be disposed on top of the DBM structure 202. In some implementations the chip assemblies 104 can be coupled to the lead frame 204 by wire bonds 206. In this implementation, three wire bonds 206 are shown: 206a, 206b, and 206c. In some implementations, the wire bond 206c has a larger diameter than the wire bonds 206a and 206b. In some implementations, the wire bond 206c includes multiple sections, e.g., 206c-1, 206c-2, and 206c-3, coupled by multiple connectors as shown in greater detail in FIG. 3. In some implementations, the semiconductor device module 100 has overall dimensions of about 10.0 to 10.5 mm×about 8.5 to 9.0 mm, or an area in the range of about 85.0 mm² to about 95.0 mm². In some implementations, the semiconductor device module 100 has a thickness in a range of about 4.0 mm to about 5.0 mm.

In some implementations, the lead frame 204 can be cut or stamped from a thin, rolled sheet of metal, e.g., copper. In some implementations, portions of the lead frame 204 are not co-planar with the die attach pad 102, e.g., some portions of the lead frame 204 can be disposed above the chip assemblies 104. Some portions of the lead frame 204 can be directly attached to the DBM structure 202, e.g., by the rigid S-shaped connector 207. Some portions of the lead frame 204 can be connected to the chip assemblies 104 by the wire bonds 206. Accordingly, some or all of the wire bonds 206 can be medium to heavy gauge wire bonds made of, e.g., aluminum. In some implementations, the ground 114 can be accessible at the lead frame 204 via such wire bonds 206.

In some implementations, the DBM structure 202 can be a direct bond copper (DBC) type structure, a direct plating copper (DPC) type structure, or a direct bond aluminum (DBA) type structure. The DBM structure 202 may be referred to as a heat spreader that provides single-sided or double-sided cooling of the chip assemblies 104. In some implementations, the DBM structure 202 has a thickness in a range of about 0.5 mm to about 3.0 mm. In some implementations, the DBM structure 202 is designed as a three-layer DBM structure that includes an internal dielectric layer (not shown) sandwiched between upper and lower metal layers. In some implementations, the dielectric layer serves as a thermal mass disposed between the two outer metal layers to draw in and absorb heat. The dielectric layer may also provide electrical insulation between the upper and lower metal layers of the DBM structure. In some implementations, the dielectric layer can be a ceramic, e.g., silicon nitride (Si₃N₄) or aluminum oxide (Al₂O₃), Si₃N₄ being a significantly more expensive ceramic material than Al₂O₃.

In some implementations, the die attach pad 102 can be formed by the upper metal layer of the DBM structure 202. In some implementations, the dielectric layer and/or the bottom metal layer of the DBM structure 202 can have a larger footprint than the DAP 102. In some implementations, the IGBT can be attached to the DAP 102 by solder 208, while the controller is attached to the DAP 102 by polyimide tape 210.

In some implementations, the controller can be configured to monitor an emitter voltage of the IGBT to determine an emitter current. Monitoring the emitter 106 can be accomplished using the sense area 116 as an intermediate connection point, wherein the emitter 106 and the current detection pad 112 are both coupled to the sense area 116 instead of being directly connected. For example, the emitter 106 can be coupled to the sense area 116 by a first wire bond 206c-3. In some implementations, the first wire bond 206c-3 can be a continuation of the wire bond 206c of length d, coupling the emitter 106 to the ground 114. The current detection pad 112 can be coupled to the sense area 116 by a second wire bond 122.

In some implementations, the second wire bond 122 coupling the controller to the sense area 116 is a gold wire while the first wire bond 206c-3 coupling the IGBT to the sense area 116 is an aluminum wire. In other words, the material of the first wire bond 206c-3 is different from the material of the second wire bond 122.

In some implementations, the semiconductor device module 100 can be encapsulated by an encapsulant 212, e.g., a polymer material such as an epoxy molding compound (EMC) that serves to seal and protect the various components of the semiconductor device module 100. The encapsulant 212 is indicated in FIG. 2 by a generic dotted line box, however, the encapsulant 212 may have a different shape. Encapsulation can be accomplished by, for example, a process of injection molding or a process of transfer molding. In some implementations, the encapsulant 212 can expose the DBM structure 202 through openings in the encapsulant 212 (not shown). In some implementations, the DBM structure 202 can be disposed in an opening in the encapsulant 212 so that the upper DBM layer, serving as the DAP 102, is exposed on the top side of the semiconductor device module 100. In some implementations, the DBM structure 202 can radiate heat from both the back side and the front side, acting as a double-sided heat sink to dissipate heat produced by the semiconductor device module 100.

FIG. 3 is a top side plan view of the semiconductor device module 100, showing the layout, relative sizes, and connections between the various components thereof, in accordance with some implementations of the present disclosure. For example, FIG. 3 shows the relative size of the IGBT die (chip assembly 104b) and the controller die (chip assembly 104a). In some implementations, the IGBT die has a much larger footprint than the footprint of the controller die. FIG. 3 also shows the relative sizes of the aluminum wire bonds, e.g., 206c-3 and the gold wire bonds, e.g., 122.

FIG. 3 further provides an enlarged view of the wire bonds 206, e.g., heavy gauge aluminum wires that extend between different levels of the semiconductor device module 100. In some implementations, such wire bonds 206 can be segmented so as to facilitate bending around a curve.

In addition to components shown in FIG. 1 and FIG. 2, FIG. 3 provides an enlarged view of multiple bonding points 300a, 300b, and 300c, along the first wire bond 206c-3 and an enlarged view of gold wires that couple the controller to the IGBT, including the second wire bond 122. The first wire bond 206c-3, being a large aluminum wire bond, needs a large bonding pad, whereas gold wires such as the second wire bond 122 can connect easily to a small bonding pad using gold ball bonding. Aluminum wire bonds such as the first wire bond 206c-3 can carry large currents, for example, currents that exceed 10 A. Each of the multiple bonding points 300a, 300b, and 300c can have a looped shape to provide a secure contact to the emitter 106 of the IGBT, and to the current sense area 116. The use of gold wires with gold balls at the connection points on the controller die avoids challenges associated with aluminum wire bonds, e.g., wedge bonds, that are prone to failure, in particular, when the polyimide tape 210 is used as a die bonding agent. That is, aluminum wedge bonds can be incompatible with the polyimide tape 210 used to bond the controller die to the DAP such that, over time, increased resistance of the aluminum wedge bond degrades the electrical connection. The combination of an aluminum wedge type of wire bond and polyimide tape can be weakened when subjected to vibrations that occur during an ultrasonic cleaning process. This failure mode is not as likely to occur on the IGBT die, which is attached to the DAP by soldering instead of the polyimide tape 210.

FIG. 3 further shows that the first wire bond 206c-3 terminates at the sense area 116, while the second wire bond 122 terminates at a pad 302. The pad 302 can be located outside the sense area 116, but still within the IGBT. The pad 302 can be coupled to the sense area 116 via the DAP 102 or by a dedicated connection below the top surface of the DAP 102. The separation between these two termination points helps to prevent degradation of the surface of the sense area 116, while maintaining an electrical connection between the first wire bond 206c-3 and the second wire bond 122.

FIG. 3 further provides an enlarged view of the sense area 116, which is disposed inside the IGBT, or chip assembly 104b. There are several reasons for this placement of the sense area 116. In some implementations, it may be more cost effective to enlarge the IGBT die to accommodate the sense area 116 than to enlarge the controller die, since the controller die tends to be more costly due to the gold wire bonding. Further, the second wire bond 122, which is a gold wire bond, can be shorter when the sense area 116 is located on the IGBT than if it were located on the lead frame 204. Consequently, the second wire bond 122 can be stronger and less expensive in the disclosed configuration. In some implementations, it may also be more cost effective to locate the sense area on the IGBT rather than on the lead frame 204 because the lead frame pattern would need to be modified to accommodate a sense pad. In addition, if the sense area 116 were to be located on the lead frame 204, the lead frame 204 would likely need additional isolation. For at least these reasons, it may be desirable to place the sense area 116 on the IGBT die, on chip assembly 104b.

FIG. 4 is a pictorial perspective view of a semiconductor device module 400, in accordance with some implementations of the present disclosure. The implementation shown in FIG. 4 has some differences from the implementation shown in FIGS. 2 and 3. In the implementation shown in FIG. 4, components and electrical connectivity of the semiconductor device module are substantially the same as those shown in FIGS. 2 and 3, but the sizes and arrangement of the components and wiring are different. For example, in the implementation shown in FIG. 4, the sense area 116 can be disposed on an island, e.g., on a third chip assembly 104c, disposed between the first chip assembly 104a and the second chip assembly 104b. The third chip assembly 104c that includes the sense area 116 can be attached to the DAP 102 by solder 208.

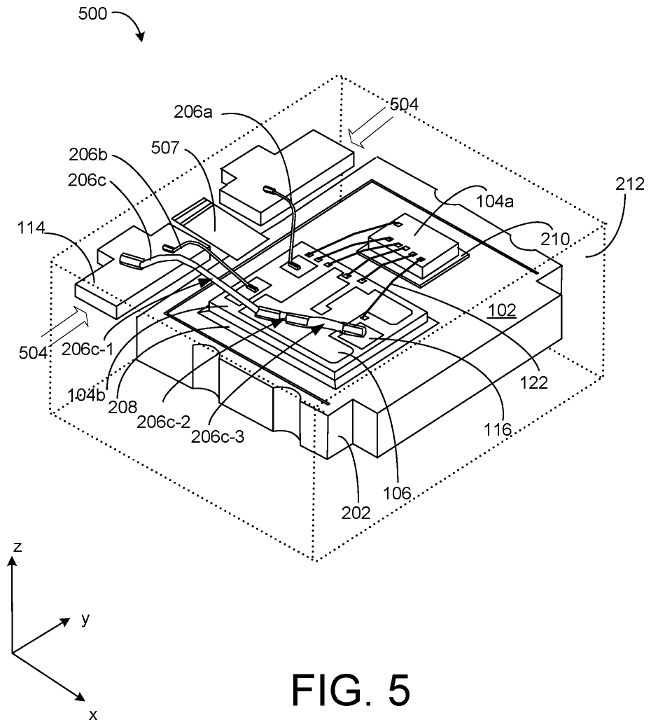

FIG. 5 is a pictorial perspective view of a semiconductor device module 500, in accordance with some implementations of the present disclosure. FIG. 5 has some differences from the implementations shown in FIGS. 2, 3, and 4. In the implementation shown in FIG. 5, the components and electrical connectivity of the semiconductor device module are substantially the same as in the previous implementations, but the sizes and arrangement of the components and wiring are different. For example, in the implementation shown in FIG. 5, the top surface of a lead frame 504, can be made level with the top surface of the DBM structure 202, that is, the DAP 102, so that a substantially straight lead frame connector 507 can replace the rigid S-shaped connector 207. The lead frame 504 is co-planar with the DAP 102 instead of being on a level above the DBC structure 202. In some implementations according to FIG. 5, the placement of the chip assemblies 104a and 104b can be the same as the implementation shown in FIGS. 2 and 3, in which the sense area 116 is located on the chip assembly 104b. Alternatively, in some implementations, the placement of the chip assemblies can be the same as the implementation shown in FIG. 4, in which the sense area 116 is located on the chip assembly 104c.

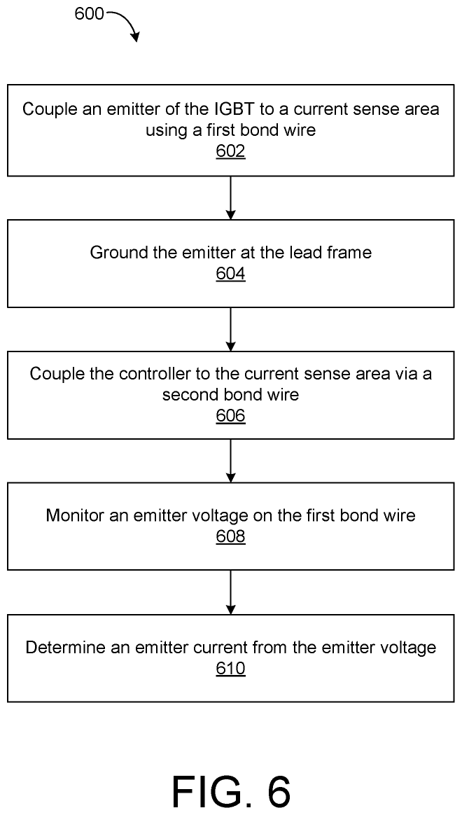

While various implementations shown in FIGS. 2, 3, 4, and 5 are presented herein, other implementations in which circuit components are re-arranged, and the wire bonds are re-routed accordingly, can be used. It is noted that, in each of such possible implementations, the electrical connectivity of the semiconductor device module 100 is substantially equivalent to that shown in FIGS. 2, 3, 4, and 5, and described below with reference to FIG. 6.

FIG. 6 is a flow chart illustrating a method 600 for electrically monitoring a chip assembly 104, e.g., the IGBT of the semiconductor device module 100, in accordance with some implementations of the present disclosure. Operations 602-610 of the method 600 can be carried out, according to some implementations as described below, with reference to FIGS. 1, 2, and 3 above. Operations of the method 600 can be performed in a different order, or not performed, depending on specific applications. It is noted that the method 600 may not completely monitor the chip assembly 104. Accordingly, it is understood that additional processes can be provided before, during, or after method 600, and that some of these additional processes may be briefly described herein.

At 602, the method 600 includes coupling an emitter of the IGBT to the sense area 116 using a first wire bond 206c-3. The first wire bond 206c-3 can be an aluminum bond wire that is attached to the sense area 116 using solder, for example,

At 604, the method 600 includes grounding the emitter 106 of the IGBT at the lead frame 204. The ground connection can be made by a bond wire having a length d as shown in FIG. 1. In some implementations, the first wire bond 206c-3 can be a portion of the wire bond 206c. The wire bond 206c can have a resistance in a range of about 1-5 mΩ.

At 606, the method 600 includes coupling the controller to the sense area 116 via a second wire bond 122. The second wire bond 122 can be a small diameter wire because it is not necessary to carry a large current. Consequently, the second bond wire can be a gold wire.

At 608, the method 600 includes monitoring the voltage at the emitter 106 on the first wire bond 206c-3.

At 610, the method 600 includes determining an emitter current from the emitter voltage. For example, the emitter current can be calculated from the emitter voltage and the resistance of the wire bond that connects to the emitter 106. In some implementations, the IGBT current is at least 10A and the voltage generated on the emitter 106 is in a range of about 20-40 mV. The wire bond 206c, including the first wire bond 206c-3 is therefore desirably a large diameter wire that can carry a large current. In some implementations, the diameter of the wire bond 206c can be about 200 μm. while the wire bonds 206a and 206b can have diameters of about 155 μm.

As described above, various implementations of a semiconductor device module for use in high-power applications incorporate a lead frame and a wire bonding scheme that are designed to improve reliability and reduce cost. A combination of aluminum wire bonds and gold wire bonds can be used when the IC chips being connected have different sizes, and when different materials are used to bond the chips to a substrate. Instead of making direct connections between the chips, the different wire bonds can be coupled to an intermediate floating pad.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus, comprising:
a substrate;
a first die coupled to the substrate and having a current sense area;
a first wire bond coupled to the first die at plurality of bonding points; and
a second die coupled to the substrate, the second die coupled to the current sense area by a second wire bond.

2. The apparatus of claim 1, wherein the second die is attached to the substrate by a polyimide tape.

3. The apparatus of claim 1, wherein one of the plurality of bonding points is in the current sense area.

4. The apparatus of claim 1, wherein the first die includes an insulated gate bipolar transistor (IGBT), and the current sense area is internal to the IGBT.

5. The apparatus of claim 4, wherein one of the plurality of bonding points is at an emitter of the IGBT.

6. The apparatus of claim 5, wherein the first wire bond is configured to carry a current between the emitter and ground and no current between the emitter and the current sense area.

7. The apparatus of claim 1, wherein a first bonding pad at the current sense area for the first wire bond is separated from a second bonding pad at the current sense area for the second wire bond.

8. The apparatus of claim 1, wherein a material of the first wire bond includes aluminum.

9. The apparatus of claim 1, wherein a material of the second wire bond includes gold.

10. The apparatus of claim 1, wherein the first wire bond is grounded to a lead frame.

11. The apparatus of claim 1, wherein the second die is configured to sense current in the first wire bond.

12. The apparatus of claim 1, wherein the current sense area is configured to operate without current flow.

13. The apparatus of claim 1, wherein the current sense area is electrically floating.

14. The apparatus of claim 1, wherein the first wire bond and the second wire bond are coupled to bonding points by gold balls.

15. A method, comprising:
coupling an emitter of an insulated gate bipolar transistor (IGBT) device on a substrate to a current sense area via a first wire bond;
coupling a controller adjacent to the IGBT device on the substrate to the current sense area via a second wire bond;
monitoring, by the controller, a voltage at the emitter using the first wire bond; and
determining from the voltage an emitter current.

16. The method of claim 15, wherein coupling to a current sense area comprises coupling to a floating pad.

17. The method of claim 15, further comprising coupling the emitter to ground via the first wire bond.

18. An apparatus, comprising:
a first integrated circuit (IC) chip coupled to a lead frame, the first IC chip attached to a substrate using solder;
a second IC chip attached to the substrate using polyimide tape;
a first wire bond coupling the lead frame to the first IC chip; and
a second wire bond coupling the first IC chip to the second IC chip.

19. The apparatus of claim 18, wherein the second IC chip is configured to monitor and control the first IC chip via a floating current sense pad.

20. The apparatus of claim 19, wherein the first wire bond and the second wire bond are both coupled to the floating current sense pad.
